(19) United States
(12) Patent Application Publication
(10) Pub. No.: US 2007/0058472 A1
(43) Pub. Date: Mar. 15, 2007

(54) Fuse structure for semiconductor device and controlling method thereof

(76) Inventor: Pei-Hsiang Chen, Hsinchu City (TW)

Correspondence Address: J C PATENTS, INC., 4 VENTURE, SUITE 250, IRVINE, CA, 92618, US

(21) Appl. No.: 11/220,786

(22) Filed: Sep. 6, 2005

(51) Int. Cl. G11C 17/18

(52) U.S. Cl. 365/225.7

(57) ABSTRACT

A fuse structure for a semiconductor device including a plurality of fuses, n first control lines, m second control lines, n first switches, and m second switches is described. In the above fuse structure, the fuses are including a first terminal and a second terminal respectively and arranged in (n×m) array. Each of the first control lines is separately coupled with the first terminals of the fuses in the same row, and each of the second control lines is separately coupled with the second terminals of the fuses in the same column. Each of the first switches is coupled with each of the first control lines, and each of the second switches is coupled with each of the second control lines.

### BACKGROUND OF THE INVENTION

1. Field of Invention

The present invention relates to a fuse structure for a semiconductor device and a control method thereof. In particular, it relates to a fuse structure for a high density semiconductor device and the control method thereof.

2. Description of Related Art

With the diminishing size of the semiconductor device, it becomes more easily affected by defects or impurities within silicon crystals. The failure of a single diode or transistor typically leads to the failure of the entire chip. For resolving this issue, redundant circuits consisting of fuses are often formed in the semiconductor device. If it is discovered that one circuit contains a defect after fabrication, one fuse can be used to switch the circuit to a disabled state and then enable a redundant circuit. In regard to the memory device, the main memory by means of redundant circuits can be coupled with a redundant memory unit, thus allowing the defective memory cell to be replaced bt one good memory cell at its address. Another reason for using the fuse in integrated circuit is to have, for example, the control bytes such as the ID code be permanently programmed into the chip.

Typically, corresponding to the method of which the fuse is to be blown off, the fuse can be designated as a laser fuse and an electronic fuse. The laser fuse uses laser beam for cutting the fuses, while the electronic fuse uses currents to blow open.

Regarding the design of the typical integrated circuit, usually a protective layer covered by silicon nitride, silicon dioxide, or the both to form. During the laser blowing of the polysilicon fu se or the metal fuse, the layout of the laser fuses typically requires the formation of an opening in the top layer for preventing damages to the protective layer. In addition, the laser needs to be precisely aimed at the fuse so as not to damage adjacent devices. However, often because of the excessive energy used, damages such as dents are formed in the protective layer.

In regard to the design of the electronic fuse, the polysilicon fuse is often adopted, which requires a high voltage to generate a current big enough to blow the fuse open. The so-called blown open fuse can be the fuse showing burnt cracks with discontinuity in the fuse structure (fracture) to become open, or the polysilicon fuse having a post-burn resistance significantly high to be viewed as being open. Therefore, the shortcomings such as, damages to the neighboring devices or damages to the wafer caused by excessive laser energy during blowing off the laser fuse, can be prevented.

Currently, whether the electronic fuse is blown or not is controlled by the transistors coupled to the fuse. Under the circumstances that one transistor controls one electronic fuse, as the number of the electronic fuses is increased, the number of the corresponding transistors is likewise increased. However, due to the size of the transistor being pretty large; it will not be conducive towards the miniaturization of the semiconductor device under the condition of having excessive number of transistors.

### SUMMARY OF THE INVENTION

In consideration of the above, the objective of the present invention is to provide a fuse structure for a semiconductor device, which can significantly reduce the number of transistors for the purpose of device miniaturization.

The objective of the present invention is to provide a control method for a fuse structure, which uses fewer transistors for controlling the fuse structure.

The present invention proposes a fuse structure for a semiconductor device, which includes a plurality of fuses, n first control lines, m second control lines, n first switches, and m second switches. Wherein, the fuses are individually having a first terminal and a second terminal, and the fuses are arranged in an (nxm) array type. Each of the first control line is separately coupled with the first terminals of the fuses in the same row, and the second control line is separately coupled with the second terminals of the fuses of the same column. Each of the first switch is separately coupled with each of the first control line, and each of second switch is separately coupled with each of the second control line.

According to an embodiment of the present invention in the fuse structure of the aforementioned semiconductor device, n≧2, and n is a whole number.

According to an embodiment of the present invention in the fuse structure of the aforementioned semiconductor device, m≧2, and m is a whole number.

According to an embodiment of the present invention in the fuse structure of the aforementioned semiconductor device, the fuses include an electronic fuse.

According to an embodiment of the present invention in the fuse structure of the aforementioned semiconductor device, the material of the first control line and the second control line includes metals.

According to an embodiment of the present invention in the fuse structure of the aforementioned semiconductor device, the first switches and the second switches include metal oxide semiconductor transistors.

According to an embodiment of the present invention in the fuse structure of the aforementioned semiconductor device, the semiconductor device includes a memory device.

The present invention proposes a control method of the fuse structure suitable for use at a semiconductor device. The fuse structure has a plurality of fuses, a plurality of first control lines, a plurality of second control lines, a plurality of first switches, and a plurality of second switches. The fuses are arranged in the style of an array. Each of the first control line is separately coupled to the first terminals of the fuses in the same row, and the second control line is separately coupled to the second terminals of the fuses in the same column. The first terminal of each of the first switch is separately coupled with each of the first control line, and the first terminal of each of the second switch is separately coupled to each of the second control line. The present invention also provides the control method of the fuse structure. The first switches are coupled with the first voltage and the second switches are coupled with the second voltage. The second voltage is smaller than the first voltage. Then, the selected first switches and the selected second switches are turned open, thus generating current to flow through the corresponding fuse.

According to an embodiment of the present invention, in the control method of the aforementioned fuse structure, the current is large enough for blowing off the fuses.

As described in the above, in the fuse structure for the semiconductor device, the fuses are arranged in an array of high density. Because one switch inputs the signal to one or more fuses, the number of switches can be greatly decreased, which is beneficial for device miniaturization. In addition, the control method of the fuse structure uses one of the first switches and one of the second switches for controlling one corresponding fuse. Therefore, fewer transistors are used for achieving the control of the fuse structure.

It is to be understood that both the foregoing general description and the following detailed description are exemplary, and are intended to provide further explanation of the invention as claimed.

### BRIEF DESCRIPTION OF THE DRAWINGS

The accompanying drawing is included to provide a further understanding of the invention, and is incorporated in and constitute a part of this specification. The drawing illustrates an embodiment of the invention and, together with the description, serves to explain the principles of the invention.

FIG. 1 is a circuit diagram schematically illustrating a fuse structure, according to an embodiment of the present invention.

### DESCRIPTION OF THE PREFERRED EMBODIMENTS

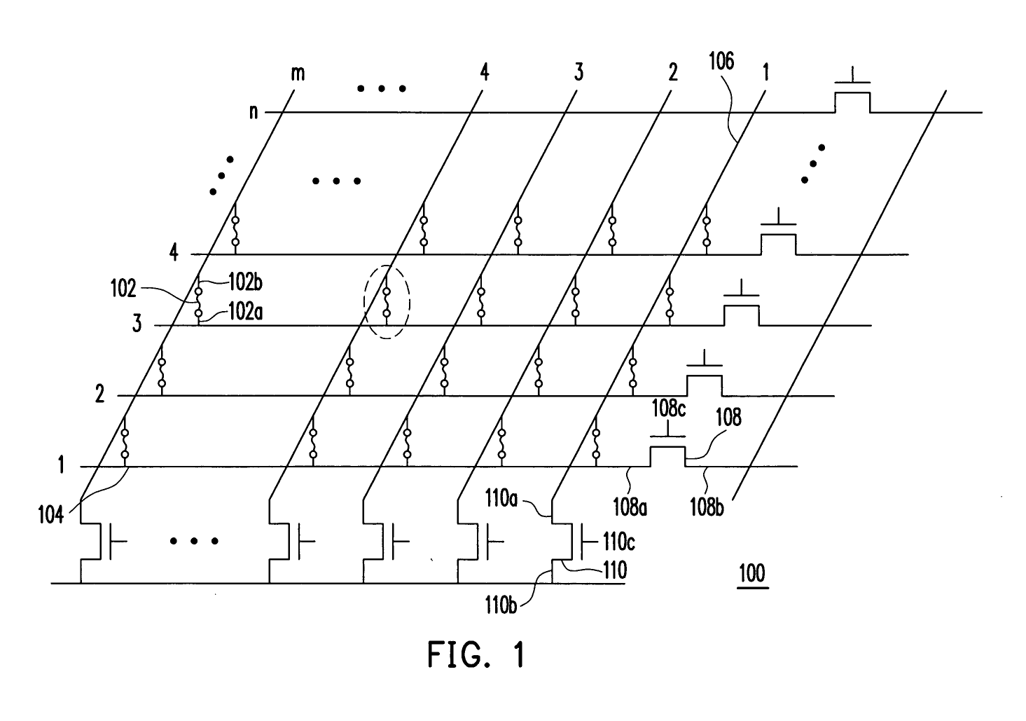

FIG. 1 is a circuit diagram schematically illustrating a fuse structure, according to an embodiment of the present invention.

Referring to FIG. 1, a fuse structure 100 for a semiconductor device proposed in the present invention includes a plurality of fuses 102, a plurality of control lines 104, a plurality of control lines 106, a plurality of switches 108, and a plurality of switches 110. The aforementioned semiconductor device is, for example, a memory device. In addition, the fuse structure 100 is, for example, coupled with a main memory in the memory device and a redundant memory in a redundant circuit.

In the present embodiment, the number of the fuses 102 is, for example, (n×m). The number of the control lines 104 is, for example, n. The number of the control lines 106 is, for example, m. The number of the switches 108 is for example n. The number of the switches 110 is for example m. Herein, n and m are whole numbers larger than two.

The fuse 102, is, for example, an electronic fuse made of polysilicon. Each fuse 102 has a terminal 102a and a terminal 102b. The fuses 102 are arranged in the fuse structure in an array.

The material of the control line 104 can be, for example, copper, aluminum, or other metals. Each of the control line 104 is separately coupled with the terminals 102a of the fuses 102 in the same row.

The material of the control line 106 can be, for example, copper, aluminum, or other metals. Each of the control line 106 is separately coupled with the terminals 102b of the fuses 102 in the same column.

The switch 108, for example, is a metal oxide semiconductor transistor. The switch 108 has a terminal 108a, a terminal 108b, and a gate terminal 108c. Wherein, the terminal 108a for each of the switch 108 is separately coupled with a control line 104.

The switch 110, for example, is a metal oxide semiconductor transistor. The switch 110 has a terminal 110a, a terminal 110b, and a gate terminal 110c. The terminal 110a for each of the switch 110 is separately coupled with a control line 106.

For the aforementioned fuse structure 100, the fuse 102 is arranged in a style of an array, which can be of high density. Because each of the switches 108 can use the corresponding control line 104 for inputting the signal to the fuses 102 in the same row and each of the switches 110 can use the corresponding control line 106 for inputting the signal to the fuses 102 in the same column, the numbers of switches 108 and 110 can be greatly reduced for achieving device miniaturization. For example, if n and m are 10 respectively, there are one hundred fuses 102 in the fuse structure 100 and ten switches 108 and ten switches 110( a total of twenty switches), are required for controlling the fuses. For the conventional technology in the similar situation, one hundred fuses would require one hundred switches for controlling the fuses under the condition one switch for controlling one fuse. When compared with the conventional technology, the present invention needs eighty switches less, thus dramatically reducing the device size.

The following serves to describe the control method for the aforementioned fuse structure 100.

Referring to FIG. 1, at first, the predetermined fuse 102 to be blown off is selected, for example, to be the fuse 102 coupled with the third control line 104 and the fourth control line 106 (as indicated by the hash line circle in FIG. 1).

The terminal 108b of each switch 108 is separately coupled with a first voltage, and the terminal 110b for each switch 110 is taken to be separately coupled with a second voltage. The second voltage is smaller than the first voltage.

Later, a voltage is applied at the gate terminal 108c of the switch 108 coupling with the third control line 104 to make the switch 108 controlling the third control line 104 to be in an open state. And a voltage is applied at the gate terminal 110c of the switch 110 coupling with the fourth control line 106 to make the switch 108 controlling the fourth control line 106 to be in an open state. As a result, a voltage difference due to the first voltage being larger than the second voltage exists and a current flowing through the selected fuse 102 is thus formed. Such current is, for example, large enough for blowing off the fuse 102.

In summary, the control method of the fuse structure proposed in the present invention is used among an array composed of a plurality of fuses 102, using one of the switch 108 and one of the switch 110 for controlling the corresponding fuse 102. As a result, fewer switches 108 and 110 are used for controlling the fuse structure 110.

Based on the aforementioned, the present invention has at least the following advantages:
1. The fuse structure for the semiconductor device proposed in the present invention is a fuse structure of high density. In addition, because one of the switches inputs a signal to more than one fuse, it can effectively reduce the number of switches, thus beneficial for device miniaturization.
2. In the control method for the fuse structure proposed in the present invention, two switches are used for controlling a corresponding fuse. Therefore, fewer transistors are used for controlling the fuse structure.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A fuse structure for a semiconductor device, comprising:
a plurality of fuses, wherein the fuses are individually having a first terminal and a second terminal, and the fuses are arranged in an (n×m) array;
n first control lines, wherein each of the first control lines is separately coupled with the first terminals of the fuses in a same row;
m second control lines, wherein each of the second control lines is separately coupled with the second terminals of the fuses in a same column;
n first switches, wherein each of the first switches is separately coupled with each of the first control lines; and
m second switches, wherein each of the second switches is separately coupled with each of the second control lines.

2. The fuse structure according to claim 1, wherein n≧2, and n is a whole number.

3. The fuse structure according to claim 1, wherein m≧2, and m is a whole number.

4. The fuse structure according to claim 1, wherein the fuses comprise of electronic fuses.

5. The fuse structure according to claim 1, wherein a material of the first control lines and the second control lines comprises of a metal.

6. The fuse structure according to claim 1, wherein the first switches and the second switches comprise of metal oxide semi-conductor transistors.

7. The fuse structure according to claim 1, wherein the semiconductor device comprises of a memory device.

8. A control method for the fuse structure according to claim 1, comprising:
coupling the first switches with a first voltage;
coupling the second switches with a second voltage, and the second voltage is smaller than the first voltage;
opening a selected first switch and a selected second switch to generate a current flowing through one corresponding fuse, wherein the fuses are arranged in an array, each of the first control lines is separately coupled with a plurality of first terminals of the fuses in a same row, the second control line is separately coupled with a plurality of second terminals of the fuses in a same column, a first terminal for each of the first switches is separately coupled with each of the first control lines, a first terminal for each of the second switches is separately coupled with each of the second control lines.

9. The control method of the fuse structure according to claim 8, wherein the current is larger or equal to a current required for blowing the fuses.

10. The control method of the fuse structure according to claim 8, wherein the fuses comprise of electronic fuses.

11. The control method of the fuse structure according to claim 8, wherein a material of the first control lines and the second control lines comprises of a metal.

12. The control method of the fuse structure according to claim 8, wherein the first switches and the second switches comprise of metal oxide semiconductor transistors.

13. The control method of the fuse structure according to claim 8, wherein the semiconductor device comprises of a memory device.
